(19) United States
(12) Patent Application Publication
(10) Pub. No.: US 2018/0304320 A1
(43) Pub. Date: Oct. 25, 2018

(54) SUBSTRATE PROCESSING APPARATUS AND HAND SHOWER GUN

(71) Applicant: Ebara Corporation, Tokyo (JP)

(72) Inventors: Hiroshi Aono, Tokyo (JP); Hideo Aizawa, Tokyo (JP); Tadakazu Sone, Tokyo (JP); Kenji Shinkai, Tokyo (JP); Nobutaka Omata, Tokyo (JP)

(21) Appl. No.: 16/019,824

(22) Filed: Jun. 27, 2018

Related U.S. Application Data
(62) Division of application No. 15/060,368, filed on Mar. 3, 2016.

(30) Foreign Application Priority Data
Mar. 6, 2015 (JP) 2015-045278
Mar. 12, 2015 (JP) 2015-049896

(51) Int. Cl. B08B 9/093; B08B 3/02; B24B 37/34; B24B 37/04; H01L 21/67

(52) U.S. Cl. CPC B08B 9/093; B08B 3/028; H01L 21/67051; B24B 37/04; B24B 37/34

(57) ABSTRACT

A substrate processing apparatus includes a substrate processing part 3 and a washing unit 40. The washing unit 40 includes a main body 43 having a liquid supplying port 41 and a liquid jetting port 42, a flow channel 44 formed between the liquid supplying port 41 and the liquid jetting port 42, and a valve 45 provided in the flow channel 44. In the washing unit 40, when the valve 45 is opened, the flow channel 44 is opened, thereby causing the liquid jetting port 42 to jet liquid, and when the valve 45 is closed, the flow channel 44 is closed, thereby causing the liquid jetting port 42 to stop jetting liquid. The flow channel 44 is provided with a water-hammer reducing mechanism 48 that operates to reduce damage to the flow channel 44 caused by a water hammer phenomenon when the valve 45 is closed.

This is a division of U.S. patent application Ser. No. 15/060,368 filed Mar. 3, 2016, which claims the benefit of Japanese Patent Application No. 2015-045278 filed Mar. 6, 2015, and Japanese Patent Application No. 2015-049896 filed Mar. 12, 2015, each of which is incorporated herein by reference in its entirety.

### BACKGROUND OF THE INVENTION

### Field of the Invention

The present disclosure relates to a substrate processing apparatus having a function of reducing damage caused by a water hammer phenomenon.

### Description of the Related Art

In a substrate polishing device for polishing semiconductor substrates (wafers), polishing liquid having been used for polishing a substrate may adhere to a component of the polishing part or the inner surfaces and ceiling of the polishing chamber. When it is left as is, such adhering polishing liquid may be dried out and repeatedly deposited so that there is a possibility that the deposited polishing liquid drops down to a substrate or adheres to a polishing surface of the polishing pad to cause a scratch on a substrate that is being polished.

In a conventional substrate processing apparatus with a hand shower (for example, Japanese Patent Laid-Open No. 9-29637), polishing liquid adhering to a component of the polishing part or the inner walls and ceiling of the polishing chamber is manually washed away on a regular basis (preferably, before the polishing liquid is dried out) using pure water (ultrapure water).

However, the conventional hand shower, which is configured to start/stop discharging water by manually operating an operation lever (a handle), includes no measure for a water hammer phenomenon that may occur when discharging water is stopped. Meanwhile, an extremely high level (class) of cleanliness management is required for devices for processing semiconductor substrates. For example, since the hand shower is made of plastic and the pipe (the pure-water supplying tube) thereof is configured by a non-oil-treated product, there is a limit to improvement of the pressure resistance. Therefore, there is a risk of damage to the hand shower gun and the pipe (the pure-water supplying tube) thereof caused by a water hammer phenomenon when discharging water is stopped.

The present disclosure has been achieved in view of the above problems, and an object of the present disclosure is to provide a substrate processing apparatus, a hand shower gun, and a water-hammer reducing mechanism capable of reducing damage caused by a water hammer phenomenon.

### SUMMARY OF THE INVENTION

A substrate processing apparatus of the present disclosure includes a substrate processing part that performs substrate processing in a chamber and a washing unit that performs washing in the chamber. The washing unit includes a main body that has a liquid supplying port and a liquid jetting port, a flow channel that is formed between the liquid supplying port and the liquid jetting port in the main body, and a valve that is provided in the flow channel. In the washing unit, when the valve is opened, the flow channel is opened, thereby causing the liquid jetting port to jet liquid, and when the valve is closed, the flow channel is closed, thereby causing the liquid jetting port to stop jetting liquid. The flow channel is provided with a water-hammer reducing mechanism that operates to reduce damage to the flow channel caused by a water hammer phenomenon when the valve is closed.

According to the above configuration, when the valve is closed to cause the liquid jetting port of the washing unit in the substrate processing apparatus to stop jetting liquid, the water-hammer reducing mechanism operates. Consequently, damage to the flow channel caused by a water hammer phenomenon is reduced.

In some embodiments, in the substrate processing apparatus of the present disclosure, the flow channel includes a first flow channel between the liquid supplying port and the valve, a second flow channel between the valve and the liquid jetting port, and a third flow channel connecting the first flow channel and the second channel without interposing the valve. The water-hammer reducing mechanism is a pressure relief valve that is provided in the third flow channel. When the valve is closed, the pressure relief valve is opened by increase in liquid pressure in the first flow channel, thereby establishing communication between the first flow channel open and the second flow channel.

According to the above configuration, when the valve is closed, the pressure relief valve is opened by the liquid pressure in the first flow channel, thereby establishing the communication between the first flow channel and the second flow channel through the third flow channel so that the liquid pressure in the first flow channel is prevented from increasing excessively. Consequently, damage to the flow channel caused by a water hammer phenomenon is reduced.

In some embodiments, in the substrate processing apparatus of the present disclosure, the pressure relief valve is configured to be kept closed by an energizing member (biasing member). An energizing pressure (biasing pressure) by the energizing member is higher than a normal liquid pressure in the first flow channel and is lower than a breakage generating pressure at which the flow channel is broken by a water hammer phenomenon.

According to the above configuration, since the energizing pressure of the pressure relief valve is lower than the breakage generating pressure, breakage of the flow channel caused by a water hammer phenomenon can be prevented. In this case, the energizing pressure of the pressure relief valve is higher than the normal liquid pressure in the first flow channel. Consequently, at the normal time (when no water hammer phenomenon occurs) in which the valve is closed, the pressure relief valve is prevented from being opened to establish the communication between the first flow channel and the second flow channel, thereby preventing liquid from jetting out (leaking) from the liquid jetting port.

In some embodiments, in the substrate processing apparatus of the present disclosure, the washing unit includes a piston that is provided in the valve and slidingly moves in cooperation with an opening/closing operation of the valve and a cylinder chamber that houses the piston. The flow channel includes a first flow channel between the liquid supplying port and the valve, a second flow channel between the valve and the liquid jetting port, and a fourth flow channel connecting the first flow channel and the cylinder chamber. A fluid resistance of the fourth flow channel is higher than a fluid resistance of the first flow channel.

According to the above configuration, when the valve is closed, liquid flows into the cylinder chamber from the fourth flow channel with the sliding movement of the piston. However, in this case, since the fluid resistance of the fourth flow channel is higher than that of the first flow channel, the flow speed (the inflow rate per unit time) of the liquid to the cylinder chamber is lowered. Accordingly, the sliding movement speed of the piston is lowered and the closing speed of the valve is lowered. In this way, since the closing speed of the valve is lowered, the liquid pressure in the first flow channel is prevented from increasing excessively when the valve is closed. Consequently, damage to the flow channel caused by a water hammer phenomenon is reduced. In this case, the water-hammer reducing mechanism can be considered to have a configuration in which the fluid resistance of the fourth flow channel is higher than the fluid resistance of the first flow channel.

In some embodiments, in the substrate processing apparatus of the present disclosure, the fourth flow channel is provided with a fluid-resistance adjusting part that adjusts the fluid resistance of the fourth flow channel.

According to the above configuration, since the fluid resistance of the fourth flow channel is adjustable, the moving speed of the piston (that is, the speed of closing the valve) can be appropriately adjusted.

In some embodiments, in the substrate processing apparatus of the present disclosure, the cylinder chamber includes a first area in which the piston slidingly moves when the valve is opened and a second area that is an area at the opposite side of the first area across the piston. The cylinder chamber is provided with a fifth flow channel connecting the first area and the second area. The fifth flow channel is provided with a check valve. When the valve is opened, the check valve is opened by increase in liquid pressure in the first area, thereby establishing communication between the first area and the second area.

According to the above configuration, when the valve is opened, the check valve is opened by the liquid pressure in the first area in the cylinder chamber, thereby establishing the communication between the first area and the second area through the fifth flow channel so that liquid is allowed to move from the first area to the second area. Consequently, the liquid pressure is prevented from blocking the sliding movement of the piston to allow the smooth sliding movement of the piston.

In some embodiments, in the substrate processing apparatus of the present disclosure, the substrate processing part is a polishing part that polishes a substrate in the chamber. The washing unit is a hand shower gun that washes an inside of the chamber.

According to the above configuration, the hand shower gun is provided with the water-hammer reducing mechanism to reduce damage to the flow channel caused by a water hammer phenomenon.

In some embodiments, in the substrate processing apparatus of the present disclosure, the substrate processing part is a polishing part that polishes a substrate in the chamber. The washing unit is an atomizer that washes the polishing part in the chamber.

According to the above configuration, the atomizer is provided with the water-hammer reducing mechanism to reduce damage to the flow channel caused by a water hammer phenomenon.

A substrate processing apparatus of the present disclosure includes a substrate processing part that performs substrate processing in a chamber, a washing unit that performs washing in the chamber, and a liquid supplying line that supplies liquid to the washing unit. The washing unit includes a main body that has a liquid supplying port and a liquid jetting port, a flow channel that is formed between the liquid supplying port and the liquid jetting port in the main body, and a valve that is provided in the flow channel. In the washing unit, when the valve is opened, the flow channel is opened, thereby causing the liquid jetting port to jet liquid, and when the valve is closed, the flow channel is closed, thereby causing the liquid jetting port to stop jetting liquid. The liquid supplying line is provided with a water-hammer reducing mechanism that operates to reduce damage to the flow channel caused by a water hammer phenomenon when the valve is closed.

According to the above configuration, when the valve is closed to cause the liquid jetting port of the washing unit in the substrate processing apparatus to stop jetting liquid, the water-hammer reducing mechanism operates. Consequently, damage to the flow channel caused by a water hammer phenomenon is reduced. When the liquid supplying line is provided with the water-hammer reducing mechanism, the water-hammer reducing mechanism may be placed directly in the middle of the liquid supplying line, or may be placed in another line (for example, a liquid discharging line) that branches from the middle of the liquid supplying line.

In some embodiments, in the substrate processing apparatus of the present disclosure, the water-hammer reducing mechanism is configured by a pressure relief valve that is provided in a liquid discharging line that branches from the liquid supplying line. When the valve is closed, the pressure relief valve operates to reduce damage to the flow channel caused by a water hammer phenomenon.

According to the above configuration, the pressure relief valve is provided to reduce damage to the flow channel caused by a water hammer phenomenon.

In some embodiments, in the substrate processing apparatus of the present disclosure, the water-hammer reducing mechanism is configured by a buffer tank that is provided in the liquid supplying line. The buffer tank includes a diaphragm that operates to reduce damage to the flow channel caused by a water hammer phenomenon when the valve is closed.

According to the above configuration, the buffer tank including the diaphragm is provided to reduce damage to the flow channel caused by a water hammer phenomenon.

In some embodiments, in the substrate processing apparatus of the present disclosure, the water-hammer reducing mechanism is configured by a pressure sensor and a pressure relief valve that are provided in the liquid discharging line that branches from the liquid supplying line. When the valve is closed and the pressure sensor detects increase in pressure in the liquid supplying line, the pressure relief valve operates to reduce damage to the flow channel caused by a water hammer phenomenon.

According to the above configuration, the pressure sensor and the pressure relief valve are provided to reduce damage to the flow channel caused by a water hammer phenomenon.

A hand shower gun of the present disclosure includes a main body that has a liquid supplying port and a liquid jetting port, a flow channel that is formed between the liquid supplying port and the liquid jetting port in the main body, a valve that is provided in the flow channel, and an operation handle that opens/closes the valve. When the valve is opened by an opening operation of the operation handle, the flow channel is opened, thereby causing the liquid jetting port to jet liquid, and when the valve is closed by a closing operation of the operation handle, the flow channel is closed, thereby causing the liquid jetting port to stop jetting liquid. The flow channel in the main body is provided with a water-hammer reducing mechanism that operates when the valve is closed by the closing operation of the operation handle.

According to the above configuration, when the valve is closed by the closing operation of the operation handle to cause the liquid jetting port of the hand shower gun to stop jetting liquid, the water-hammer reducing mechanism operates. Consequently, damage to the flow channel in the main body of the hand shower gun caused by a water hammer phenomenon is reduced.

In some embodiments, in the hand shower gun of the present disclosure, the flow channel includes a first flow channel between the liquid supplying port and the valve, a second flow channel between the valve and the liquid jetting port, and a third flow channel connecting the first flow channel and the second flow channel without interposing the valve. The water-hammer reducing mechanism is a pressure relief valve that is provided in the third flow channel. When the valve is closed by the closing operation of the operation handle, the pressure relief valve is opened by increase in liquid pressure in the first flow channel, thereby establishing communication between the first flow channel and the second flow channel.

According to the above configuration, when the valve is closed by the closing operation of the operation handle, the pressure relief valve is opened by the liquid pressure in the first flow channel, thereby establishing the communication between the first flow channel and the second flow channel through the third flow channel so that the liquid pressure in the first flow channel is prevented from increasing excessively. Consequently, damage to the flow channel caused by a water hammer phenomenon is reduced.

In some embodiments, in the hand shower gun of the present disclosure, the pressure relief valve is configured to be kept closed by an energizing member. An energizing pressure by the energizing member is higher than a normal liquid pressure in the first flow channel and is lower than a breakage generating pressure at which the flow channel is broken by a water hammer phenomenon.

According to the above configuration, since the energizing pressure of the pressure relief valve is lower than the breakage generating pressure, breakage of the flow channel caused by a water hammer phenomenon can be prevented. In this case, since the energizing pressure of the pressure relief valve is higher the normal liquid pressure in the first flow channel, at the normal time (when no water hammer phenomenon occurs) in which the valve is closed, the pressure relief valve is prevented from being opened to establish the communication between the first flow channel and the second flow channel, thereby preventing liquid from jetting out (leaking) from the liquid jetting port.

In some embodiments, in the hand shower gun of the present disclosure, the hand shower gun includes a piston that is provided in the valve and slidingly moves in cooperation with an opening/closing operation of the valve and a cylinder chamber that houses the piston. The flow channel includes a first flow channel between the liquid supplying port and the valve, a second flow channel between the valve and the liquid jetting port, and a fourth flow channel connecting the first flow channel and the cylinder chamber. A fluid resistance of the fourth flow channel is higher than a fluid resistance of the first flow channel.

According to the above configuration, when the valve is closed by the closing operation of the operation handle, liquid flows into the cylinder chamber from the fourth flow channel to the cylinder chamber with the sliding movement of the piston. However, in this case, since the fluid resistance of the fourth flow channel is higher than the fluid resistance of the first flow channel, the flow speed (the inflow rate per unit time) of the liquid to the cylinder chamber is lowered. Accordingly, the sliding movement speed of the piston is lowered and the closing speed of the valve is lowered. In this way, since the closing speed of the valve is lowered, the liquid pressure in the first flow channel is prevented from increasing excessively when the valve is closed. Consequently, damage to the flow channel caused by a water hammer phenomenon is reduced. In this case, the water-hammer reducing mechanism can be considered to have a configuration in which the fluid resistance of the fourth flow channel is higher than the fluid resistance of the first flow channel.

In some embodiments, in the hand shower gun of the present disclosure, the fourth flow channel is provided with a fluid-resistance adjusting part that adjusts the fluid resistance of the fourth flow channel.

According to the above configuration, since the fluid resistance of the fourth flow channel is adjustable, the moving speed of the piston (that is, the speed of closing the valve) can be appropriately adjusted.

In some embodiments, in the hand shower gun of the present disclosure, the cylinder chamber includes a first area in which the piston slidingly moves when the valve is opened by the opening operation of the operation handle and a second area that is an area at an opposite side of the first area across the piston. The cylinder chamber is provided with a fifth flow channel connecting the first area and the second area. The fifth flow channel is provided with a check valve. When the valve is opened by the opening operation of the operation handle, the check valve is opened by increase in liquid pressure in the first area, thereby establishing communication between the first area and the second area.

According to the above configuration, when the valve is opened by the opening operation of the operation handle, the check valve is opened by the liquid pressure in the first area in the cylinder chamber, thereby establishing the communication between the first area and the second area through the fifth flow channel so that liquid is allowed to move from the first area to the second area. Consequently, the liquid pressure is prevented from blocking the sliding movement of the piston to allow the smooth sliding movement of the piston. In this way, the opening operation of the operation handle can be smoothly performed.

In a water-hammer reducing mechanism of the present disclosure, a flow channel is formed between a liquid supplying port and a liquid jetting port and the water-hammer reducing mechanism operates when a valve provided in the flow channel is closed. The flow channel includes a first flow channel between the liquid supplying port and the valve, a second flow channel between the valve and the liquid jetting port, and a third flow channel connecting the first flow channel and the second channel without interposing the valve. The water-hammer reducing mechanism is a pressure relief valve that is provided in the third flow channel. When the valve is closed, the pressure relief valve is opened by increase in liquid pressure in the first flow channel, thereby establishing communication between the first flow channel and the second flow channel.

According to the above water-hammer reducing mechanism, similarly to the above hand shower gun, when the valve is closed, the pressure relief valve is opened by the liquid pressure in the first flow channel, thereby establishing the communication between the first flow channel and the second flow channel through the third flow channel so that the liquid pressure in the first flow channel is prevented from increasing excessively. Consequently, damage to the flow channel caused by a water hammer phenomenon is reduced.

In a water-hammer reducing mechanism of the present disclosure, a flow channel is formed between a liquid supplying port and a liquid jetting port and the water-hammer reducing mechanism operates when a valve provided in the flow channel is closed. The valve is provided with a piston that is housed in a cylinder chamber and slidingly moves in cooperation with an opening/closing operation of the valve. The flow channel includes a first flow channel between the liquid supplying port and the valve, a second flow channel between the valve and the liquid jetting port, and a fourth flow channel connecting the first flow channel and the cylinder chamber. A fluid resistance of the fourth flow channel is higher than a fluid resistance of the first flow channel.

According to the above water-hammer reducing mechanism, similarly to the above hand shower gun, when the valve is closed, liquid flows into the cylinder chamber from the fourth flow channel with the sliding movement of the piston. However, in this case, since the fluid resistance of the fourth flow channel is higher than the fluid resistance of the first flow channel, the flow speed (the inflow rate per unit time) of liquid to the cylinder chamber is lowered. Accordingly, the sliding movement speed of the piston is lowered and the closing speed of the valve is lowered. In this way, since the closing speed of the valve is lowered, the liquid pressure in the first flow channel is prevented from increasing excessively when the valve is closed. Consequently, damage to the flow channel caused by a water hammer phenomenon is reduced.

According to the present disclosure, damage caused by a water hammer phenomenon is reduced.

### BRIEF DESCRIPTION OF THE DRAWINGS

FIG. 1 is a plan view of the entire configuration of a substrate processing apparatus in an embodiment of the present disclosure;

FIG. 2 is a pure-water supplying pipe of a polishing part of the substrate processing apparatus in the embodiment of the present disclosure;

FIG. 3 is a plan view of the polishing unit of the substrate processing apparatus in the embodiment of the present disclosure;

FIG. 4 is an explanatory diagram of a hand shower gun (in a housed state) in the embodiment of the present disclosure;

FIG. 5 is an explanatory diagram of a hand shower gun in a first embodiment of the present disclosure;

FIG. 6 is an explanatory diagram of the hand shower gun (when water discharge is being performed) in the first embodiment of the present disclosure;

FIG. 7 is an explanatory diagram of the hand shower gun (when water discharge is stopped) in the first embodiment of the present disclosure;

FIG. 8 is an explanatory diagram of an atomizer in a modification of the first embodiment of the present disclosure;

FIG. 9 is an explanatory diagram of a hand shower gun in a second embodiment of the present disclosure;

FIG. 10 is an explanatory diagram of the hand shower gun (when water discharge is being performed) in the second embodiment of the present disclosure;

FIG. 11 is an explanatory diagram of the hand shower gun (when water discharge is stopped) in the second embodiment of the present disclosure;

FIG. 12 is an explanatory diagram of an atomizer in a modification of the second embodiment of the present disclosure;

FIG. 13 is an explanatory diagram of a hand shower gun in a third embodiment of the present disclosure;

FIG. 14 is an explanatory diagram of the hand shower gun (when water discharge is being performed) in the third embodiment of the present disclosure;

FIG. 15 is an explanatory diagram of the hand shower gun (when water discharge is stopped) in the third embodiment of the present disclosure;

FIG. 16 is an explanatory diagram of an atomizer in a modification of the third embodiment of the present disclosure;

FIG. 17 is an explanatory diagram of a substrate processing apparatus in another embodiment of the present disclosure;

FIG. 18 is an explanatory diagram of a substrate processing apparatus in still another embodiment of the present disclosure; and

FIG. 19 is an explanatory diagram of a substrate processing apparatus in still another embodiment of the present disclosure.

### DETAILED DESCRIPTION OF THE PREFERRED EMBODIMENTS

Hereinafter, descriptions of a substrate processing apparatus in an embodiment of the present disclosure will be given with reference to the drawings. In the present embodiment, an example of the substrate processing apparatus that is used as a substrate polishing device or the like is shown, for example. Identical or corresponding components are denoted by identical reference numerals and the overlapping explanations thereof will be omitted.

### First Embodiment

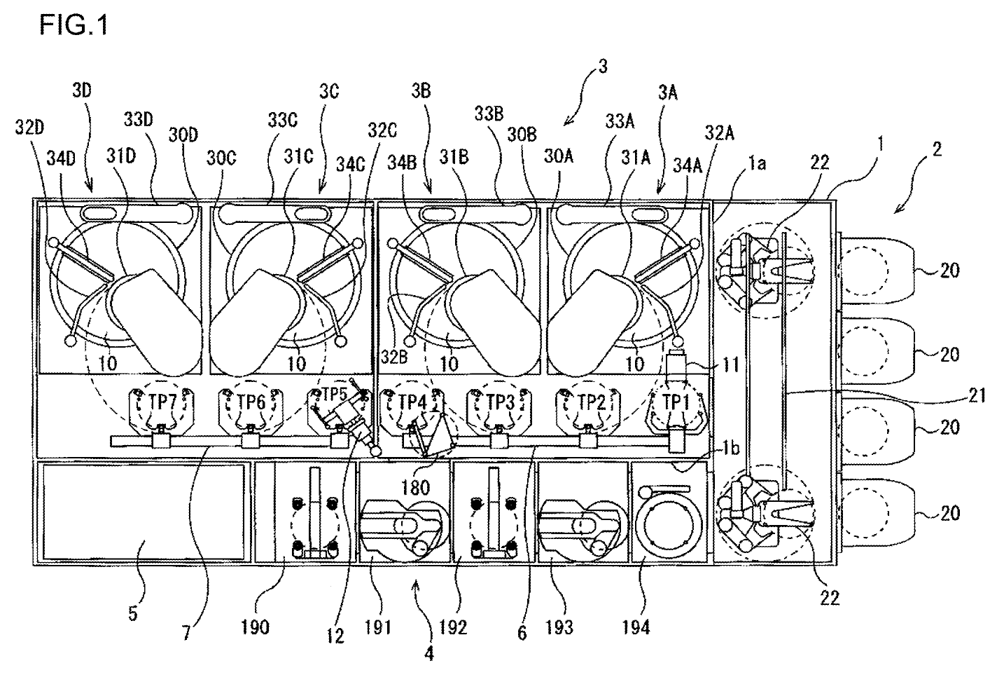

FIG. 1 is a plan view of the entire configuration of a substrate processing apparatus (a substrate polishing device) in an embodiment of the present disclosure. As illustrated in FIG. 1, the substrate processing apparatus includes a housing 1 having a substantially rectangular shape. Partition walls 1a and 1b partition the housing 1 into a loading/unloading part 2, a polishing part 3, and a washing part 4. The loading/unloading part 2, the polishing part 3, and the washing part 4 are assembled independently from one another and are independently ventilated. The substrate processing apparatus further includes a control part 5 that controls substrate processing operations.

The polishing part 3 is a region in which a wafer is polished (flattened) and includes a first polishing unit 3A, a second polishing unit 3B, a third polishing unit 3C, and a fourth polishing unit 3D. As illustrated in FIG. 1, the first polishing unit 3A, the second polishing unit 3B, the third polishing unit 3C, and the fourth polishing unit 3D are aligned in the longitudinal direction of the substrate processing apparatus.

As illustrated in FIG. 1, the first polishing unit 3A includes a polishing table 30A having a polishing pad 10 with a polishing surface attached thereon, a top ring 31A that holds a wafer and polishes the wafer while pressing the wafer against the polishing pad 10 on the polishing table 30A, a polishing-liquid supplying nozzle 32A that supplies polishing liquid or dressing liquid (for example, pure water) to the polishing pad 10, a dresser 33A that dresses the polishing surface of the polishing pad 10, and an atomizer 34A that atomizes and sprays mixed fluid of liquid (for example, pure water) and gas (for example, nitrogen gas), or liquid (for example, pure water) to the polishing surface.

The atomizer 34A is intended to wash away polishing wastes and abrasive grains remaining on the polishing surface of the polishing pad 10 with high-pressure fluid. Washing the polishing surface with the fluid pressure by the atomizer 34A and dressing the polishing surface, which is mechanical contact, by the dresser 33A result in more preferable dressing, that is, regeneration of the polishing surface. An atomizer generally regenerates a polishing surface after a contact-type dresser (for example, a diamond dresser) dresses the polishing surface.

The second polishing unit 3B similarly includes a polishing table 30B having the polishing pad 10 attached thereon, a top ring 31B, a polishing-liquid supplying nozzle 32B, a dresser 33B, and an atomizer 34B. The third polishing unit 3C similarly includes a polishing table 30C having the polishing pad 10 attached thereon, a top ring 31C, a polishing-liquid supplying nozzle 32C, a dresser 33C, and an atomizer 34C. The fourth polishing unit 3D similarly includes a polishing table 30D having the polishing pad 10 attached thereon, a top ring 31D, a polishing-liquid supplying nozzle 32D, a dresser 33D, and an atomizer 34D.

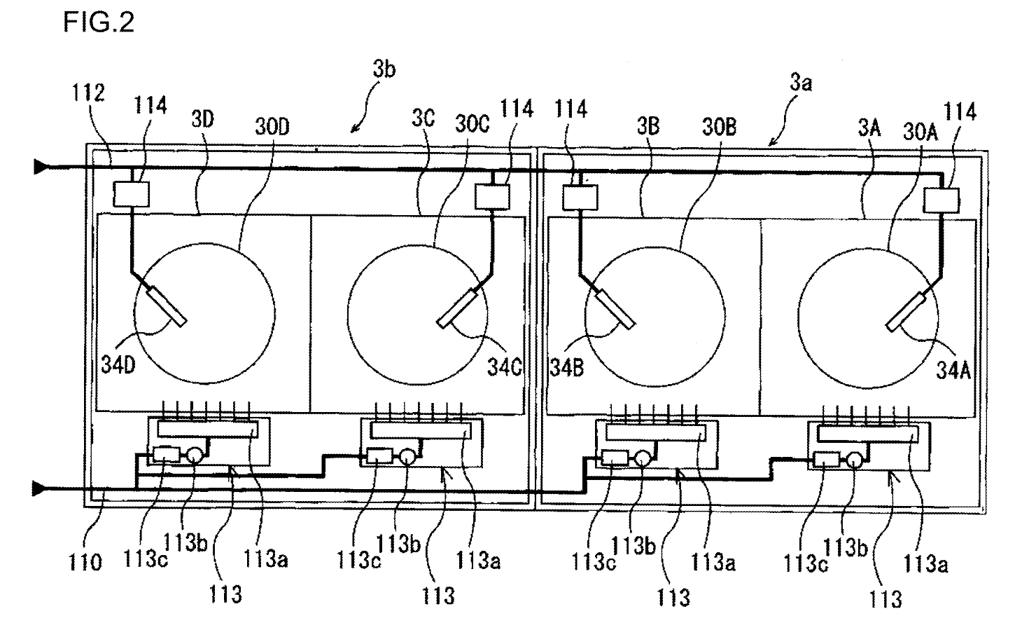

FIG. 2 is a schematic diagram of a pure-water supplying pipe of the polishing part 3. In this substrate processing apparatus, the first polishing unit 3A and the second polishing unit 3B constitute a first polishing section 3a as a single unit and the third polishing unit 3C and the fourth polishing unit 3D constitute a second polishing section 3b as a single unit. The first polishing section 3a can be separated from the second polishing section 3b. As described above, the polishing part 3 uses various types of fluid such as pure water, air, and nitrogen gas. For example, as illustrated in FIG. 2, pure water (DIW) is supplied from a pure-water supply source (not illustrated) to a pure-water supplying pipe 110 in the substrate processing apparatus. The pure-water supplying pipe 110 extends through the polishing units 3A, 3B, 3C, and 3D of the polishing part 3 and connects to respective distribution control parts 113 in the polishing units 3A, 3B, 3C, and 3D.

The pure-water supplying pipe 110 is divided at a point between the first polishing section 3a and the second polishing section 3b. Both ends of the divided pure-water supplying pipe 110 are connected with each other by a connection mechanism (not illustrated). Examples of the use of pure water used in the polishing units include washing of the top rings (for example, washing of the outer peripheral sides of the top rings, washing of the substrate holding surfaces, and washing of the retaining rings), washing of wafer carrying hands (for example, washing of the carrying hands of first and second linear transporters), washing of polished wafers, dressing of the polishing pads, washing of the dressers (for example, washing of the dressing members), washing of the dresser arms, washing of the polishing-liquid supplying nozzles, and washing of the polishing pads by the atomizers.

Pure water is flown into the distribution control parts 113 through the pure-water supplying pipe 110 and distributed to respective use points by the distribution control parts 113. Each use point is a point at which pure water of a nozzle for washing the top rings and a nozzle for washing the dressers is used. Pure water is supplied from the distribution control part 113 to a terminal device such as a washing nozzle (for example, the above nozzle for washing the top ring or the above nozzle for washing the above dresser) that is placed in the polishing unit. For example, pure water the flow rate of which is adjusted by the respective distribution control parts 113 of the polishing units is supplied to the pure-water supplying tubes (not illustrated) of the above polishing-liquid supplying nozzles 32A to 32D, respectively. In this way, the distribution control part 113 is placed in each polishing unit. Accordingly, the number of pipes is smaller than that in the conventional structure in which pure water is supplied from a single header to polishing units through a plurality of pipes. This leads to reduction in number of the connection mechanisms for connecting the pipes between the first polishing section 3a and the second polishing section 3b and results in the simple structure and reduction of risk of leakage of pure water. Since the atomizer needs a lot of pure water, a pure-water supplying pipe 112 for the exclusive use of the atomizer is preferably provided, as illustrated in FIG. 2.

Each distribution control part 113 includes a valve box 113a that communicates with the use point of a nozzle for washing the top ring (not illustrated), the pure-water supplying tube (not illustrated) or the like, a pressure gauge 113b that is placed at an upstream side of the valve box 113a, and a flow-rate regulator 113c that is placed at an upstream side of the pressure gauge 113b. The valve box 113a has a plurality of pipes communicating with the corresponding use points and respective valves for the pipes.

The pressure gauge 113b measures the pressure of pure water that is sent to the valve box 113a. The flow-rate regulator 113c adjusts the flow rate of pure water so as to maintain the measured value by the pressure gauge 113b at a predetermined value. In this way, the polishing units independently control the flow rate of pure water. Accordingly, the influence by pure water used among the polishing units can be reduced, thereby stabilizing supply of pure water. Therefore, this solves the problem in the conventional structure that the flow rate of pure water in one polishing unit is made unstable due to pure water used in another polishing unit. Each polishing unit has the flow-rate regulator 113c in the embodiment illustrated in FIG. 2. However, one flow-rate regulator 113c may be shared by two polishing units. For example, in some embodiments, a set of the pressure gauge 113b and the flow-rate regulator 113c is placed at an upstream side of the two valve boxes 113a of the polishing units 3A and 3B and similarly a set of the pressure gauge 113b and the flow-rate regulator 113c is placed at an upstream side of the two valve boxes 113a of the polishing units 3C and 3D.

In the embodiment illustrated in FIG. 2, separately from the pure-water supplying pipes 110 for use points such as of the nozzles for washing the top rings (not illustrated), the pure-water supplying tubes (not illustrated) or the like, the pure-water supplying pipe 112 for the exclusive use of the atomizers 34A, 34B, 34C, and 34D are provided. The pure-water supplying pipe 112 is connected to the atomizers 34A, 34B, 34C, and 34D. Flow-rate control parts 114 are placed at respective upstream sides of the atomizers 34A, 34B, 34C, and 34D. The flow-rate control part 114 adjusts the flow rate of pure water supplied from the pure-water supplying pipe 112 and sends the pure water to the atomizer at the adjusted flow rate.

Similarly to the above distribution control parts 113, each flow-rate control part 114 has a valve, a pressure gauge, and a flow-rate regulator, which are arranged similarly to those in the distribution control part 113. The control part 5 controls the operations of the flow-rate regulators of the flow-rate control parts 114 based on the respective measurement values by the pressure gauges of the flow-rate control parts 114 in such a way that pure water is supplied to the atomizers at respective predetermined flow rates.

As illustrated in FIG. 2, the pure-water supplying pipe 110 and the pure-water supplying pipe 112 are independently connected to a pure-water supply source. An independent pure-water supplying route is given to the pure-water supplying pipe 110 and the pure-water supplying pipe 112, respectively. This arrangement can prevent the use of pure water in the atomizer from having an influence on the flow rates of pure water at the other use points.

FIG. 2 is an explanatory diagram of the pure-water supplying pipe 110 that supplies pure water. However, the arrangement of the pipes and the distribution control parts in FIG. 2 can be applied to supplying pipes for other fluids such as air, nitrogen gas, and slurry. For example, in some embodiments, a plurality of slurry supplying pipes that transfer a plurality of types of slurry are provided and distribution control parts each connected to the slurry supplying pipes are provided in the respective polishing units. The distribution control parts supply slurry that is selected depending on the polishing processing to the above polishing-liquid supplying nozzles. Since the distribution control part is provided for each polishing unit, the type of slurry to be supplied to the polishing-liquid supplying nozzle can vary with each polishing unit. Further, the flow rate of slurry to be supplied to the polishing-liquid supplying nozzle can be adjusted by the distribution control part.

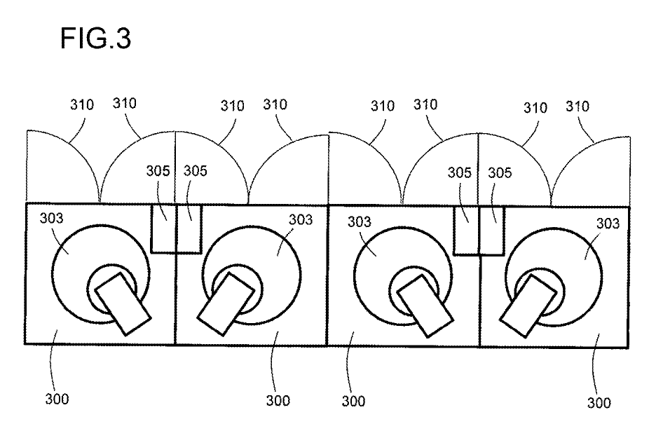

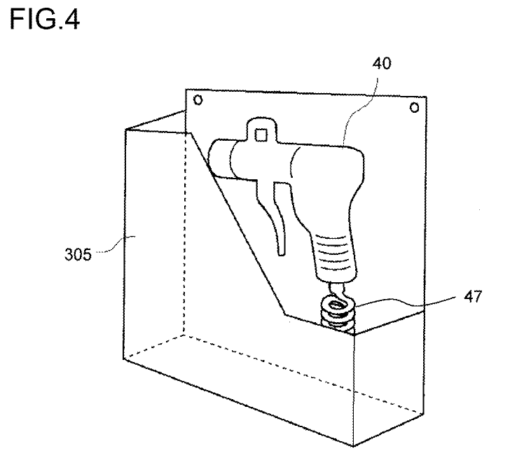

FIG. 3 is a plan view of the polishing part 3 of the substrate processing apparatus in the present embodiment. As illustrated in FIG. 3, openable maintenance doors 310 are placed at the front side (which is the upper side in FIG. 3 and corresponds to the left side in FIG. 1) of polishing chambers 300 of the polishing part 3. The maintenance doors 310 are opened to maintain the polishing part 3 from the outside of the polishing device. In each polishing chamber 300, a housing box 305 is placed at a side closer to the maintenance doors 310 of the polishing device. A hand shower gun 40 for washing the inside of the polishing chamber 300 is included in the housing box 305 (see FIG. 4).

A worker washes the inside of the polishing chamber 300 by using the hand shower gun 40. As illustrated in FIG. 4, the hand shower gun 40 is housed in the housing box 305 on the wall of the polishing chamber 300 when being not used.

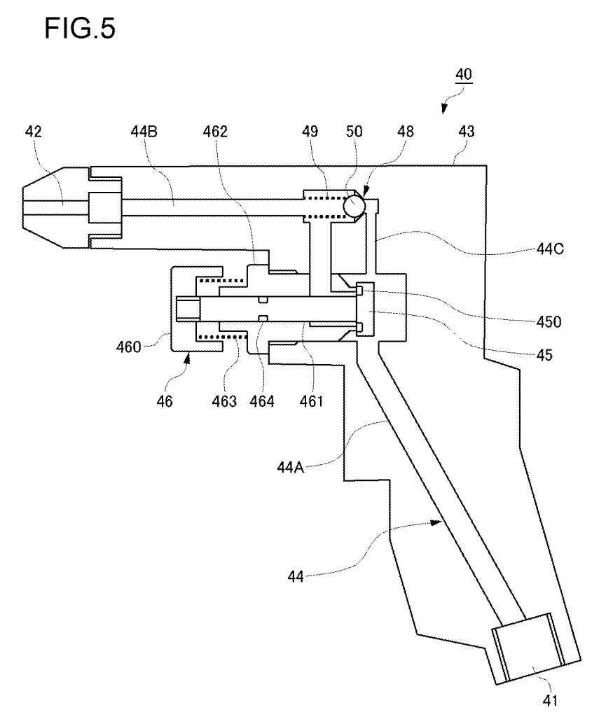

FIG. 5 is an explanatory diagram of the hand shower gun 40 of the present embodiment. As illustrated in FIG. 5, the hand shower gun 40 includes a main body 43 that has a liquid supplying port 41 and a liquid jetting port 42, a flow channel 44 that is formed between the liquid supplying port 41 and the liquid jetting port 42 in the main body 43, a valve 45 that is provided in the flow channel 44, and an operation handle 46 that opens/closes the valve 45. The flow channel 44 in the main body 43 is provided with a water-hammer reducing mechanism that operates when the valve 45 is closed by the closing operation of the operation handle 46.

The operation handle 46 includes an operation part 460, a handle slide shaft 461, and a mounting part 462. The handle slide shaft 461 is mounted to the mounting part 462 in such a way that the handle slide shaft 461 is slidable in the handle moving direction (the opening/closing direction, or the lateral direction in FIG. 5). A return spring 463 is arranged between the operation part 460 and the mounting part 462. The return spring 463 energizes the operation part 460 in the closing direction (the leftward direction in FIG. 5). A seal member 464 such as an O ring is attached to the handle slide shaft 461. The seal member 464 prevents leakage of liquid (pure water) from the flow channel 44.

The operation handle 46 is connected with the valve 45 through the handle slide shaft 461 to cooperate with the valve 45. A seal member 450 such as an O ring is attached to the valve 45. The seal member 450 prevents leakage of liquid (pure water) from a first flow channel 44A to a second flow channel 44B when the valve 45 is closed.

The hand shower gun 40 in the present embodiment is used for semiconductors (for washing precision devices with pure water). For this reason, the hand shower gun 40 is made of plastic. For example, the liquid contact part (a part that contacts with liquid) is made of polypropylene, fluororubber, or the like to prevent elution of metal ions and generation of rust. The flow channel 44 in the main body 43 and a pipe (a pipe outside the main body 43) such as a liquid supplying tube 47 of the hand shower gun 40 are configured by non-oil-treated products (see FIG. 4).

Specific descriptions of the water-hammer reducing mechanism in the present embodiment will be given below. The flow channel 44 in the main body 43 of the hand shower gun 40 is constituted by the first flow channel 44A between the liquid supplying port 41 and the valve 45, the second flow channel 44B between the valve 45 and the liquid jetting port 42, and a third flow channel 44C connecting the first flow channel 44A and the second flow channel 44B without interposing the valve 45.

The water-hammer reducing mechanism in the present embodiment is a pressure relief valve 48 that is provided in the third flow channel 44C. When the valve 45 is closed by the closing operation of the operation handle 46, the pressure relief valve 48 is opened by increase in liquid pressure in the first flow channel 44A to establish communication between the first flow channel 44A and the second flow channel 44B.

In this case, the pressure relief valve 48 is configured to be kept closed by a spring 49 energizing a ball (a valve element) 50. The energizing force (the released pressure by the pressure relief valve 48) by the spring 49 is set to be higher than the normal liquid pressure in the first flow channel 44A. That is, the released pressure by the pressure relief valve 48 is set to be higher than the supplying pressure of liquid (pure water) that is supplied to the flow channel 44 (the pipe). The released pressure by the pressure relief valve 48 is preferably as close to the supplying pressure as possible, and for example, set to 1.05 to 1.2 times of the supplying pressure.

The energizing force (the released pressure by the pressure relief valve 48) by the spring 49 is set to be lower than the breakage generating pressure at which the flow channel 44 is broken by a water hammer phenomenon. That is, the released pressure by the pressure relief valve 48 is set to be lower than the maximum pressure in the pipe at the time of occurrence of a water hammer phenomenon.

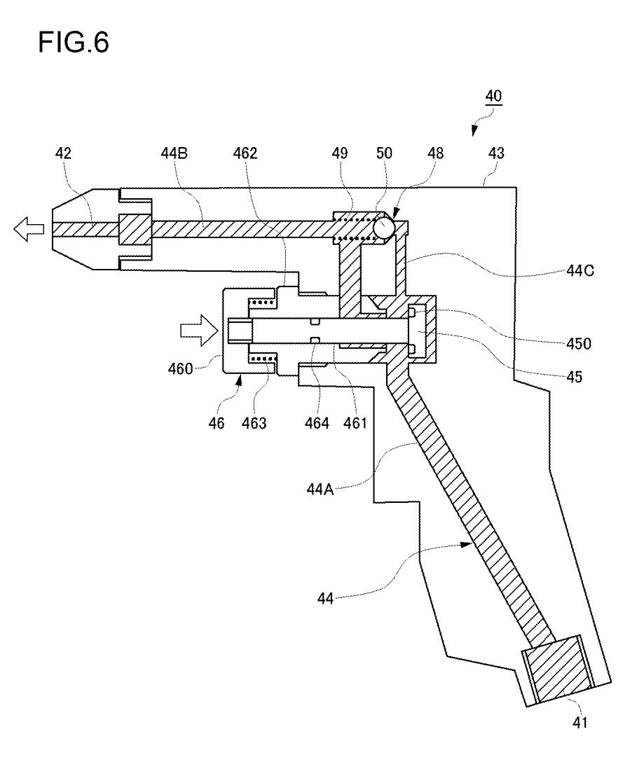

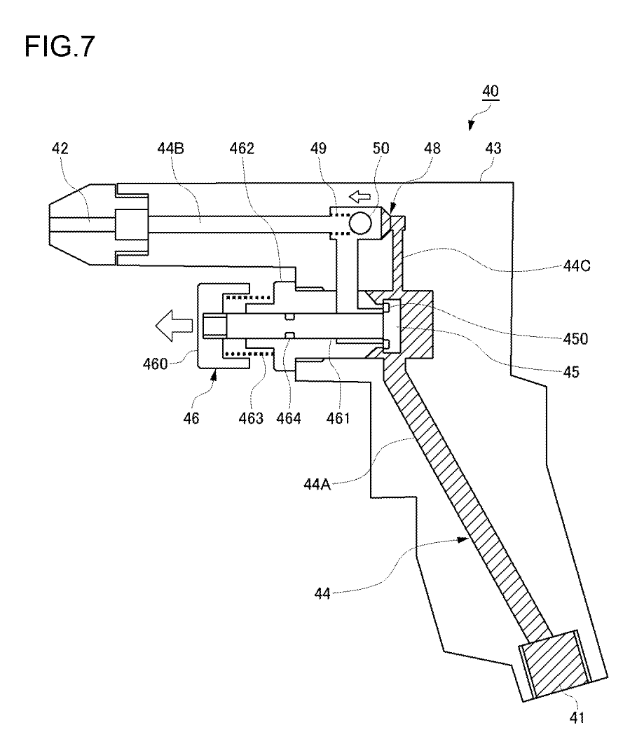

FIG. 6 is an explanatory diagram of the hand shower gun 40 in the event of the opening operation of the operation handle 46. FIG. 7 is an explanatory diagram of the hand shower gun 40 in the event of the closing operation of the operation handle 46. As illustrated in FIG. 6, the valve 45 is opened by the opening operation of the operation handle 46, the flow channel 44 is opened, thereby causing the liquid jetting port 42 to jet liquid (pure water).

As illustrated in FIG. 7, the valve 45 is closed by the closing operation of the operation handle 46, the flow channel 44 is closed, thereby causing the liquid jetting port 42 to stop jetting liquid (pure water). In this case, when the valve 45 is closed by the closing operation of the operation handle 46, increase in liquid pressure in the first flow channel 44A causes the ball (the valve element) 50 to move in the opening direction (the leftward direction in FIG. 7) against the energizing pressure by the spring 49. Accordingly, the pressure relief valve 48 is opened, thereby establishing the communication between the first flow channel 44A and the second flow channel 44B through the third flow channel 44C.

When the communication between the first flow channel 44A and the second flow channel 44B through the third flow channel 44C is established, the liquid pressure in the first flow channel 44A decreases and the energizing pressure by the spring 49 causes the ball (the valve element) 50 to move in the closing direction (the rightward direction in FIG. 7), thereby closing the pressure relief valve 48.

According to the above substrate processing apparatus in the first embodiment of the present disclosure, when the valve 45 is closed to cause the liquid jetting port 42 of the washing unit (the hand shower gun 40) in the substrate processing apparatus to stop jetting liquid (pure water), the water-hammer reducing mechanism (the pressure relief valve 48) operates. Consequently, damage to the flow channel 44 (the flow channel 44 in the hand shower gun 40, pipes outside the hand shower gun 40) caused by a water hammer phenomenon is reduced so that the lifetime of the substrate processing apparatus is prolonged.

In the present embodiment, when the valve 45 is closed, the pressure relief valve 48 is opened by the liquid pressure in the first flow channel 44A, thereby establishing the communication between the first flow channel 44A and the second flow channel 44B through the third flow channel 44C so that the liquid pressure in the first flow channel 44A is prevented from increasing excessively. Consequently, damage to the flow channel 44 (the flow channel 44 in the hand shower gun 40, pipes outside the hand shower gun 40) caused by a water hammer phenomenon is reduced.

In the present embodiment, since the energizing pressure of the pressure relief valve 48 is lower than the breakage generating pressure, breakage of the flow channel 44 caused by a water hammer phenomenon is prevented. In this case, the energizing pressure of the pressure relief valve 48 is higher than the normal liquid pressure in the first flow channel 44A. Consequently, at the normal time (when no water hammer phenomenon occurs) in which the valve 45 is closed, the pressure relief valve 48 is prevented from being opened to establish the communication between the first flow channel 44A and the second flow channel 44B, thereby preventing liquid from jetting out (leaking) from the liquid jetting port 42.

According to the hand shower gun 40 in the first embodiment of the present disclosure, when the valve 45 is closed by the closing operation of the operation handle 46 to cause the liquid jetting port 42 of the hand shower gun 40 to stop jetting liquid (pure water), the water-hammer reducing mechanism operates. Consequently, damage to the flow channel (the flow channel 44 in the main body 43, pipes outside the main body 43) of the hand shower gun 40 caused by a water hammer phenomenon is reduced so that the lifetime of the hand shower gun 40 is prolonged.

In the present embodiment, when the valve 45 is closed by the closing operation of the operation handle 46, the pressure relief valve 48 is opened by the liquid pressure in the first flow channel 44A, thereby establishing the communication between the first flow channel 44A and the second flow channel 44B through the third flow channel 44C so that the liquid pressure in the first flow channel 44A is prevented from increasing excessively. Consequently, damage to the flow channel 44 (the flow channel 44 in the main body 43, pipes outside the main body 43) caused by a water hammer phenomenon is reduced.

In the present embodiment, since the energizing pressure of the pressure relief valve 48 is lower than the breakage generating pressure, breakage of the flow channel 44 caused by a water hammer phenomenon is prevented. In this case, since the energizing pressure of the pressure relief valve 48 is higher the normal liquid pressure in the first flow channel 44A, at the normal time (when no water hammer phenomenon occurs) in which the valve 45 is closed, the pressure relief valve 48 is prevented from being opened to establish the communication between the first flow channel 44A and the second flow channel 44B, thereby preventing liquid from jetting out (leaking) from the liquid jetting port 42.

In the present embodiment, the hand shower gun 40 is provided with the water-hammer reducing mechanism to reduce damage to the flow channel 44 (the flow channel 44 in the main body 43, pipes outside the main body 43) caused by a water hammer phenomenon.

### (First Modification)

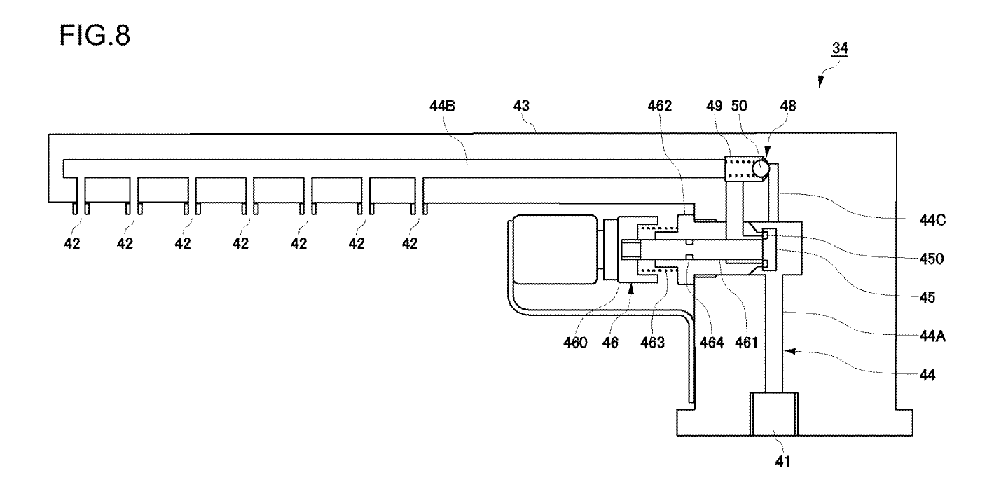

FIG. 8 illustrates a modification of the first embodiment. As illustrated in FIG. 8, the water-hammer reducing mechanism in the first embodiment may be applied to the atomizer 34. That is, the flow channel 44 that is formed in the main body 43 of the atomizer 34 is constituted by the first flow channel 44A between the liquid supplying port 41 and the valve 45, the second flow channel 44B between the valve 45 and the liquid jetting port 42, and the third flow channel 44C connecting the first flow channel 44A and the second flow channel 44B without interposing the valve 45. The pressure relief valve 48 is provided in the third flow channel 44C. When the valve 45 is closed, the pressure relief valve 48 is opened by increase in liquid pressure in the first flow channel 44A, thereby establishing the communication between the first flow channel 44A and the second flow channel 44B.

When the atomizer 34 is provided with the water-hammer reducing mechanism in this way, damage to the flow channel 44 (the flow channel 44 in the atomizer 34, pipes outside the atomizer 34) caused by a water hammer phenomenon is reduced.

### Second Embodiment

Next, descriptions will be given of a substrate processing apparatus in a second embodiment of the present disclosure. Differences between the substrate processing apparatus in the second embodiment and that in the first embodiment will be mainly described. Unless otherwise noted, the configuration and operations in the present embodiment are identical to those in the first embodiment.

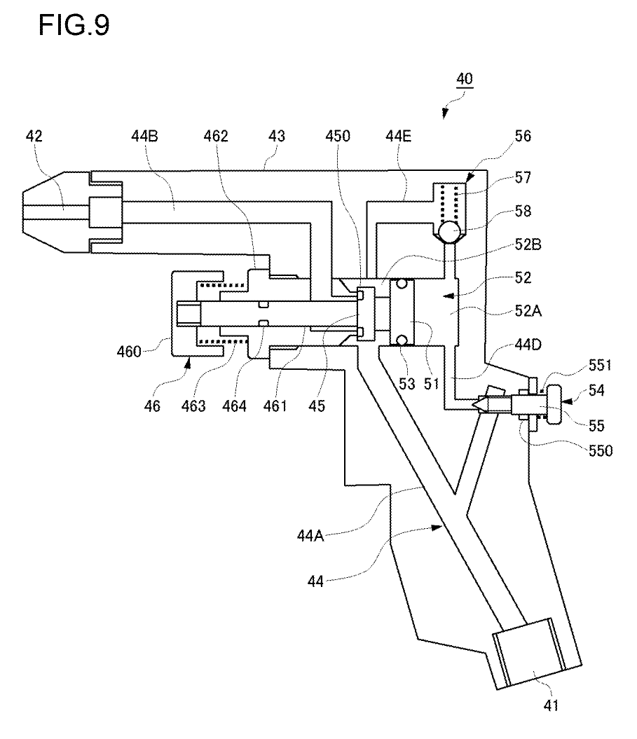

FIG. 9 is an explanatory diagram of the hand shower gun 40 in the present embodiment. As illustrated in FIG. 9, the hand shower gun 40 includes a piston 51 that slidingly moves in cooperation with the opening/closing operation of the valve 45 and a cylinder chamber 52 that houses the piston 51. The flow channel 44 that is formed in the main body 43 of the hand shower gun 40 includes the first flow channel 44A between the liquid supplying port 41 and the valve 45, the second flow channel 44B between the valve 45 and the liquid jetting port 42, and a fourth flow channel 44D connecting the first flow channel 44A and the cylinder chamber 52. In the present embodiment, a seal member 53 is placed between the outer periphery of the piston 51 and the inner periphery of the cylinder chamber 52.

In the present embodiment, the configuration in which the fluid resistance of the fourth flow channel 44D is higher than that of the first flow channel 44A is applied as the water-hammer reducing mechanism. For example, when the flow channel area of the fourth flow channel 44D is set to be smaller than that of the first flow channel 44A, the fluid resistance of the fourth flow channel 44D is made higher than that of the first flow channel 44A. Alternatively, when the flow channel length of the fourth flow channel 44D is set to be longer than that of the first flow channel 44A, the fluid resistance of the fourth flow channel 44D is made higher than that of the first flow channel 44A.

As illustrated in FIG. 9, the fourth flow channel 44D is provided with a fluid-resistance adjusting part that adjusts the fluid resistance of the fourth flow channel 44D. In this case, a throttling mechanism 54 that adjusts the flow channel area of the fourth flow channel 44D is provided as the fluid-resistance adjusting part. An adjusting screw 55 of the throttling mechanism 54 is screwed into the main body 43 of the hand shower gun 40. A seal member 550 such as an O ring is arranged between the main body 43 and the adjusting screw 55. The seal member 550 prevents leakage of liquid (pure water) from the fourth flow channel 44D. A detent spring 551 is attached to the adjusting screw 55. The detent spring 551 energizes the adjusting screw 55 (energizes in the rightward direction in FIG. 9) to prevent the looseness (unstableness) of the spring.

For example, when the adjusting screw 55 of the throttling mechanism 54 is rotated and moved in the throttle direction (the leftward direction in FIG. 9), the flow channel area of the fourth flow channel 44D becomes smaller and the fluid resistance of the fourth flow channel 44D becomes higher. When the adjusting screw 55 of the throttling mechanism 54 is rotated reversely and moved in the opposite direction (the rightward direction in FIG. 9), the flow channel area of the fourth flow channel 44D becomes larger and the fluid resistance of the fourth flow channel 44D becomes smaller. In this way, the fluid resistance of the fourth flow channel 44D is adjusted by the throttling mechanism 54 changing the flow channel area of the fourth flow channel 44D.

As illustrated in FIG. 9, the cylinder chamber 52 is divided into a first area 52A (the area at the right side in FIG. 9) in which the piston 51 slidingly moves when the valve 45 is opened by the opening operation of the operation handle 46 and a second area 52B (the area at the left side in FIG. 9) that is an area at the opposite side of the first area 52A across the piston 51. The cylinder chamber 52 is provided with a fifth flow channel 44E connecting the first area 52A and the second area 52B.

The fifth flow channel 44E is provided with a check valve 56. When the valve 45 is opened by the opening operation of the operation handle 46, the check valve 56 is opened by increase in liquid pressure in the first area 52A to establish the communication between the first area 52A and the second area 52B.

In this case, the check valve 56 is configured to be kept closed by a spring 57 energizing a ball (a valve element) 58. The energizing force (the released pressure by the check valve 56) by the spring 57 is set to be higher than the normal liquid pressure in the first area 52A in the cylinder chamber 52. That is, the released pressure by the check valve 56 is set to be higher than the supplying pressure of liquid (pure water) that is supplied to the flow channel 44.

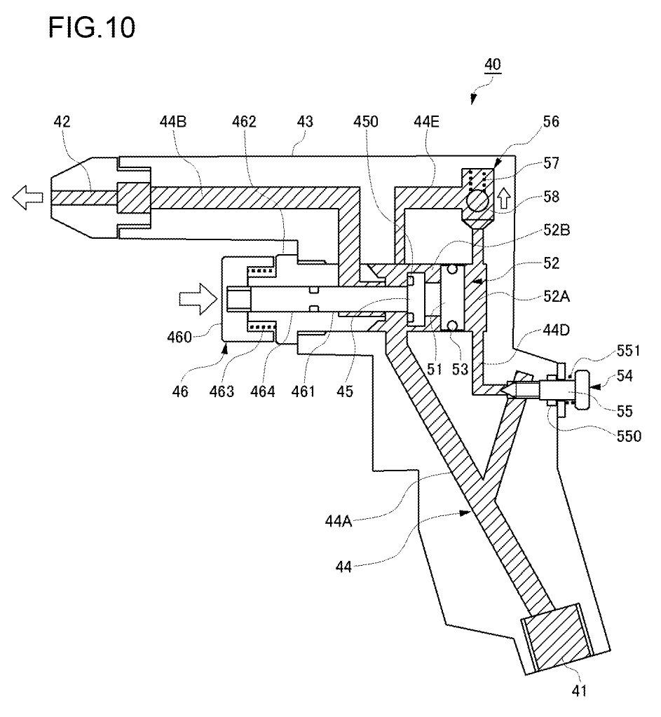

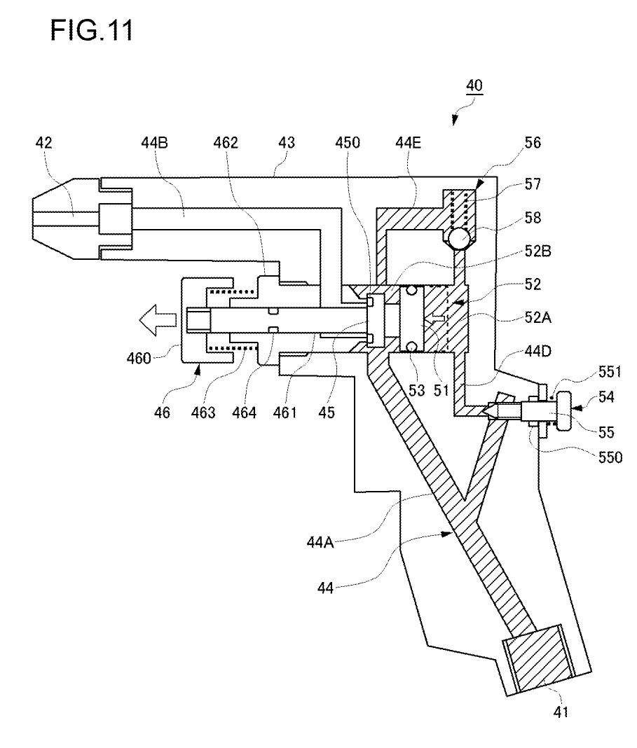

FIG. 10 is an explanatory diagram of the hand shower gun 40 in the event of the opening operation of the operation handle 46. FIG. 11 is an explanatory diagram of the hand shower gun 40 in the event of the closing operation of the operation handle 46. As illustrated in FIG. 10, the valve 45 is opened by the opening operation of the operation handle 46, the flow channel 44 is opened, thereby causing the liquid jetting port 42 to jet liquid (pure water).

In this case, when the valve 45 is opened by the opening operation of the operation handle 46, increase in liquid pressure in the first area 52A in the cylinder chamber 52 causes the ball (the valve element) 58 to move in the opening direction (the upward direction in FIG. 10) against the energizing pressure by the spring 57. Accordingly, the check valve 56 is opened, thereby establishing the communication between the first area 52A and the second area 52B through the fifth flow channel 44E so that the smooth sliding movement of the piston 51 is allowed. Thereafter, when the liquid pressure in the first area 52A in the cylinder chamber 52 decreases, the energizing pressure by the spring 57 causes the ball (the valve element) 58 to move in the closing direction (the downward direction in FIG. 10), thereby closing the check valve 56.

As illustrated in FIG. 11, when the valve 45 is closed by the closing operation of the operation handle 46, the flow channel 44 is closed, thereby causing the liquid jetting port 42 to stop jetting liquid (pure water). In this case, when the valve 45 is closed by the closing operation of the operation handle 46, liquid flows into the cylinder chamber 52 (the first area 52A) from the fourth flow channel 44D with the sliding movement of the piston 51. However, since the fluid resistance of the fourth flow channel 44D is higher than that of the first flow channel 44A, the flow speed (the inflow rate per unit time) of liquid to the cylinder chamber 52 (the first area 52A) is lowered. Accordingly, the sliding movement speed of the piston 51 is lowered and the closing speed of the valve 45 is lowered. That is, the valve 45 is configured to close slowly.

According to the above substrate processing apparatus in the second embodiment of the present disclosure, effects same as those in the first embodiment are provided. That is, damage to the flow channel 44 (the flow channel 44 in the hand shower gun 40, pipes outside the hand shower gun 40) caused by a water hammer phenomenon is reduced so that the lifetime of the substrate processing apparatus is prolonged.

In the present embodiment, when the valve 45 is closed, liquid (pure water) flows into the cylinder chamber 52 (the first area 52A) from the fourth flow channel 44D with the sliding movement of the piston 51. However, in this case, since the fluid resistance of the fourth flow channel 44D is higher than that of the first flow channel 44A, the flow speed (the inflow rate per unit time) of liquid to the cylinder chamber 52 (the first area 52A) is lowered. Accordingly, the sliding movement speed of the piston 51 is lowered and the closing speed of the valve 45 is lowered. In this way, since the closing speed of the valve 45 is lowered, the liquid pressure in the first flow channel 44A is prevented from increasing excessively when the valve 45 is closed. Consequently, damage to the flow channel 44 (the flow channel 44 in the hand shower gun 40, pipes outside the hand shower gun 40) caused by a water hammer phenomenon is reduced.

In the present embodiment, since the fluid resistance of the fourth flow channel 44D is adjustable, the moving speed of the piston 51 (that is, the closing speed of the valve 45) can be adjusted appropriately.

In the present embodiment, when the valve 45 is opened, the check valve 56 is opened by the liquid pressure in the first area 52A in the cylinder chamber 52, thereby establishing the communication between the first area 52A and the second area 52B through the fifth flow channel 44E so that liquid is allowed to move from the first area 52A to the second area 52B. Consequently, the liquid pressure is prevented from blocking the sliding movement of the piston 51 to allow the smooth sliding movement of the piston 51.

According to the hand shower gun 40 in the second embodiment of the present disclosure, effects same as those in the first embodiment are provided. That is, damage to the flow channel 44 (the flow channel 44 in the main body 43, pipes outside the main body 43) of the hand shower gun 40 caused by a water hammer phenomenon is reduced so that the lifetime of the hand shower gun 40 is prolonged.

In the present embodiment, when the valve 45 is closed by the closing operation of the operation handle 46, liquid flows into the cylinder chamber 52 (the first area 52A) from the fourth flow channel 44D with the sliding movement of the piston 51. However, in this case, since the fluid resistance of the fourth flow channel 44D is higher than that of the first flow channel 44A, the flow speed (the inflow rate per unit time) of liquid to the cylinder chamber 52 (the first area 52A) is lowered. Accordingly, the sliding movement speed of the piston 51 is lowered and the closing speed of the valve 45 is lowered. In this way, since the closing speed of the valve 45 is lowered, the liquid pressure in the first flow channel 44A is prevented from increasing excessively when the valve 45 is closed. Consequently, damage to the flow channel (the flow channel 44 in the main body 43, pipes outside the main body 43) caused by a water hammer phenomenon is reduced.

In the present embodiment, since the fluid resistance of the fourth flow channel 44D is adjustable, the moving speed of the piston 51 (that is, the closing speed of the valve 45) can be adjusted appropriately.

In the present embodiment, when the valve 45 is opened by the opening operation of the operation handle 46, the check valve 56 is opened by increase in liquid pressure in the first area 52A of the cylinder chamber 52, thereby establishing the communication between the first area 52A and the second area 52B through the fifth flow channel 44E so that liquid is allowed to move from the first area 52A to the second area 52B. Consequently, the liquid pressure is prevented from blocking the sliding movement of the piston 51 to allow the smooth sliding movement of the piston 51. In this way, the opening operation of the operation handle 46 can be performed smoothly.

### (Second Modification)

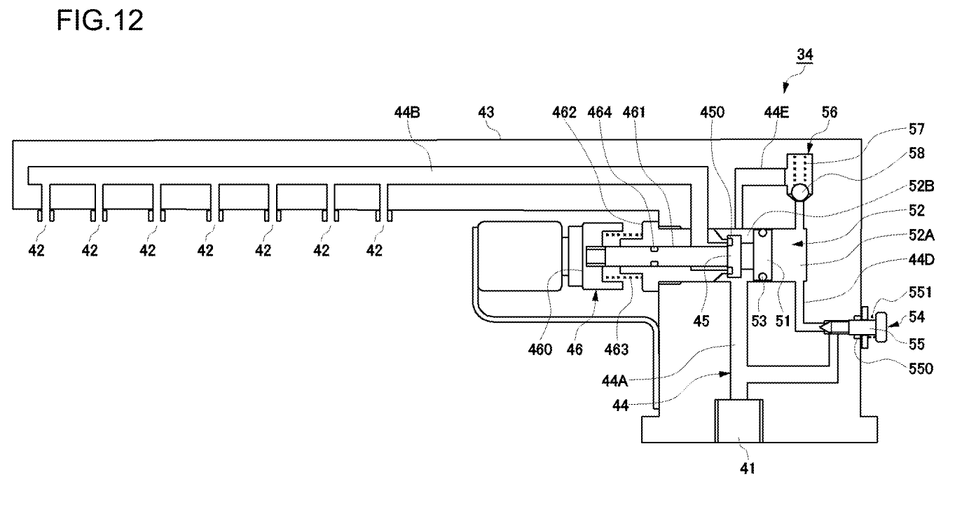

FIG. 12 illustrates a modification of the second embodiment. As illustrated in FIG. 12, the water-hammer reducing mechanism in the second embodiment may be applied to the atomizer 34. That is, the atomizer 34 includes the piston 51 that slidingly moves in cooperation with the opening/closing operation of the valve 45 and the cylinder chamber 52 that houses the piston 51. The flow channel 44 in the main body 43 of the atomizer 34 is constituted by the first flow channel 44A between the liquid supplying port 41 and the valve 45, the second flow channel 44B between the valve 45 and the liquid jetting port 42, and the fourth flow channel 44D connecting the first flow channel 44A and the cylinder chamber 52. As the water-hammer reducing mechanism, the configuration in which the fluid resistance of the fourth flow channel 44D is higher than that of the first flow channel 44A is applied.

When the atomizer 34 is provided with the water-hammer reducing mechanism in this way, damage to the flow channel 44 (the flow channel 44 in the atomizer 34, pipes outside the atomizer 34) caused by a water hammer phenomenon is reduced.

### Third Embodiment

Next, descriptions will be given of a substrate processing apparatus in a third embodiment of the present disclosure. Differences between the substrate processing apparatus in the third embodiment and that in the second embodiment will be mainly described. Unless otherwise noted, the configuration and operations in the present embodiment are identical to those in the second embodiment.

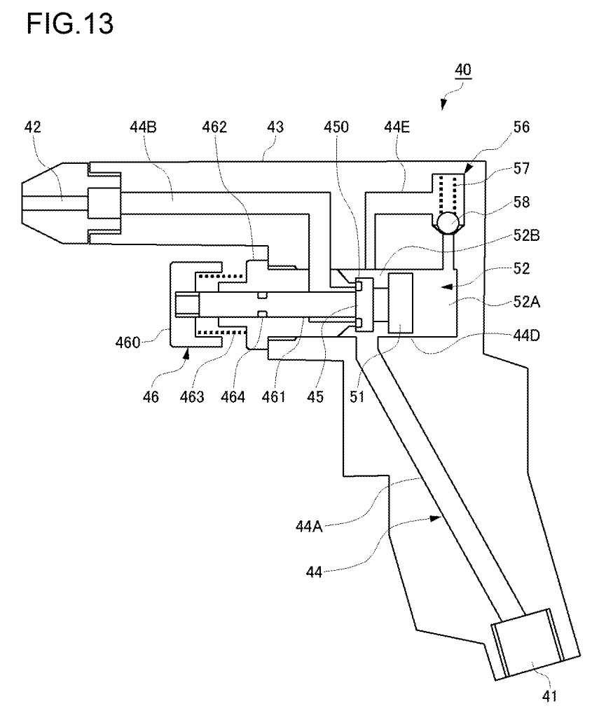

FIG. 13 is an explanatory diagram of the hand shower gun 40 in the present embodiment. As illustrated in FIG. 13, the hand shower gun 40 includes the piston 51 that slidingly moves in cooperation with the opening/closing operation of the valve 45 and the cylinder chamber 52 that houses the piston 51. The flow channel 44 in the main body 43 of the hand shower gun 40 is constituted by the first flow channel 44A between the liquid supplying port 41 and the valve 45, the second flow channel 44B between the valve 45 and the liquid jetting port 42, and the fourth flow channel 44D connecting the first flow channel 44A and the cylinder chamber 52. In the present embodiment, a gap is made between the outer periphery of the piston 51 and the inner periphery of the cylinder chamber 52. This gap forms the fourth flow channel 44D.

As the water-hammer reducing mechanism in the present embodiment, the configuration in which the fluid resistance of the fourth flow channel 44D is higher than that of the first flow channel 44A is applied. For example, when the flow channel area of the fourth flow channel 44D is set to be smaller than that of the first flow channel 44A, the fluid resistance of the fourth flow channel 44D is made higher than that of the first flow channel 44A.

As illustrated in FIG. 13, the cylinder chamber 52 is divided into the first area 52A (the area at the right side in FIG. 13) in which the piston 51 slidingly moves when the valve 45 is opened by the opening operation of the operation handle 46 and the second area 52B (the area at the left side in FIG. 13) that is an area at the opposite side of the first area 52A across the piston 51. The cylinder chamber 52 is provided with the fifth flow channel 44E connecting the first area 52A and the second area 52B.

As in the second embodiment, the fifth flow channel 44E is provided with the check valve 56. When the valve 45 is opened by the opening operation of the operation handle 46, the check valve 56 is opened by increase in liquid pressure in the first area 52A to establish the communication between the first area 52A and the second area 52B.

In this case, the closed state of the check valve 56 is configured to be kept closed by the spring 57 energizing the ball (the valve element) 58. The energizing pressure (the released pressure by the check valve 56) by the spring 57 is set to be higher than the normal liquid pressure in the first area 52A in the cylinder chamber 52. That is, the released pressure by the check valve 56 is set to be higher than the supplying pressure of liquid (pure water) that is supplied to the flow channel 44 (the pipe).

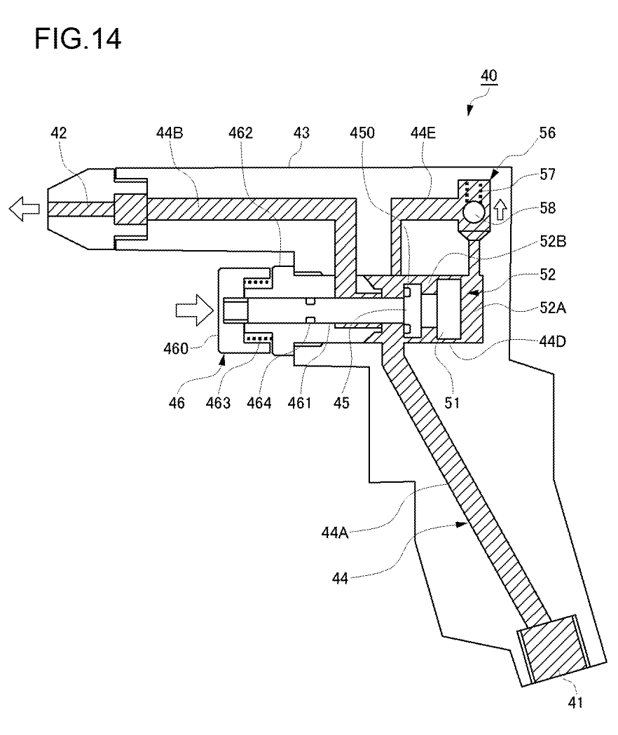

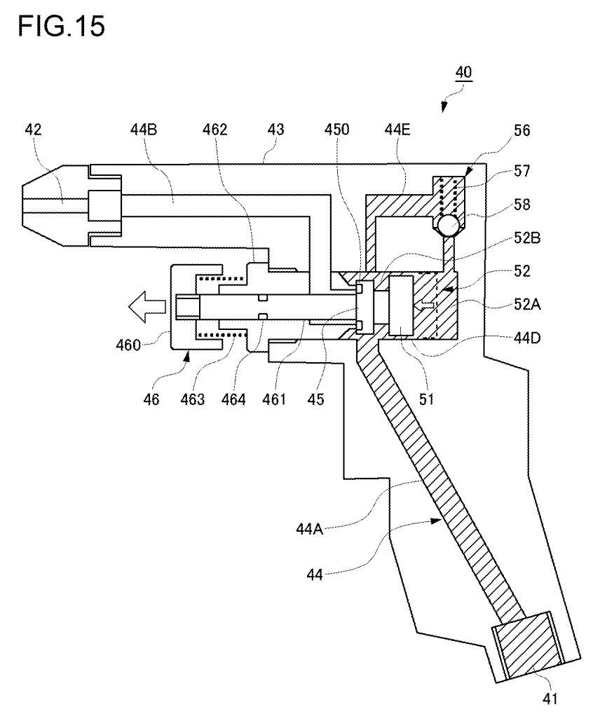

FIG. 14 is an explanatory diagram of the hand shower gun 40 in the event of the opening operation of the operation handle 46. FIG. 15 is an explanatory diagram of the hand shower gun 40 in the event of the closing operation of the operation handle 46. As illustrated in FIG. 14, the valve 45 is opened by the opening operation of the operation handle 46, the flow channel 44 is opened, thereby causing the liquid jetting port 42 to jet liquid (pure water).

In this case, when the valve 45 is opened by the opening operation of the operation handle 46, increase in liquid pressure in the first area 52A in the cylinder chamber 52 causes the ball (the valve element) 58 to move in the opening direction (the upward direction in FIG. 14) against the energizing pressure by the spring 57. Accordingly, the check valve 56 is opened, thereby establishing the communication between the first area 52A and the second area 52B through the fifth flow channel 44E so that the smooth sliding movement of the piston 51 is allowed. Thereafter, when the liquid pressure in the first area 52A in the cylinder chamber 52 decreases, the energizing pressure by the spring 57 causes the ball (the valve element) 58 to move in the closing direction (the downward direction in FIG. 14), thereby closing the check valve 56.

As illustrated in FIG. 15, when the valve 45 is closed by the closing operation of the operation handle 46, the flow channel 44 is closed, thereby causing the liquid jetting port 42 to stop jetting liquid (pure water). In this case, when the valve 45 is closed by the closing operation of the operation handle 46, liquid flows into the cylinder chamber 52 (the first area 52A) from the fourth flow channel 44D with the sliding movement of the piston 51. However, since the fluid resistance of the fourth flow channel 44D is higher than that of the first flow channel 44A, the flow speed (the inflow rate per unit time) of liquid to the cylinder chamber 52 (the first area 52A) is lowered. Accordingly, the sliding movement speed of the piston 51 is lowered and the closing speed of the valve 45 is lowered. That is, the valve 45 is configured to close slowly.

According to the above substrate processing apparatus in the third embodiment of the present disclosure, effects same as those in the second embodiment are provided. That is, damage to the flow channel 44 (the flow channel 44 in the hand shower gun 40, pipes outside the hand shower gun 40) caused by a water hammer phenomenon is reduced so that the lifetime of the substrate processing apparatus is prolonged.

According to the hand shower gun 40 in the third embodiment of the present disclosure, effects same as those in the second embodiment are provided. That is, damage to the flow channel 44 (the flow channel 44 in the main body 43, pipes outside the main body 43) of the hand shower gun 40 caused by a water hammer phenomenon is reduced so that the lifetime of the hand shower gun 40 is prolonged.

### (Third Modification)

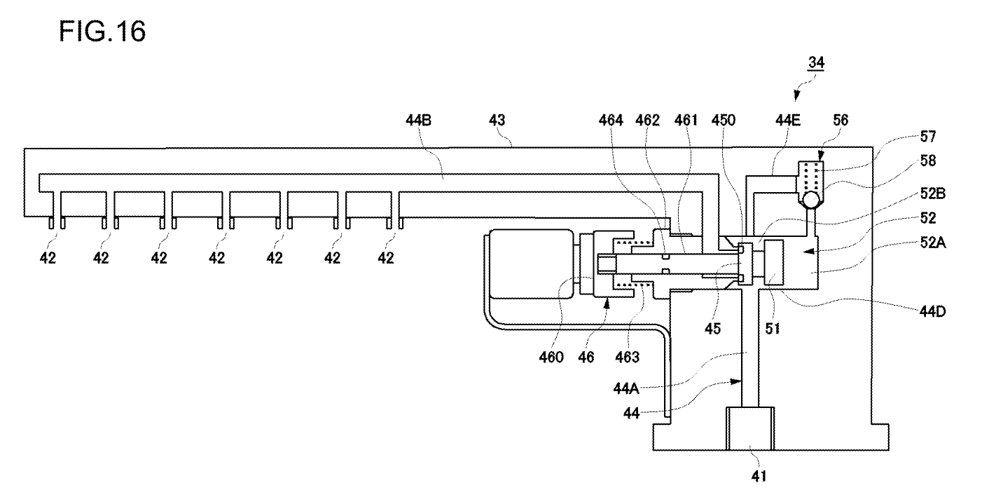

FIG. 16 illustrates a modification of the third embodiment. As illustrated in FIG. 16, the water-hammer reducing mechanism in the third embodiment may be applied to the atomizer 34. That is, the atomizer 34 includes the piston 51 that slidingly moves in cooperation with the opening/closing operation of the valve 45 and the cylinder chamber 52 that houses the piston 51. The flow channel 44 in the main body 43 of the hand shower gun 40 is constituted by the first flow channel 44A between the liquid supplying port 41 and the valve 45, the second flow channel 44B between the valve 45 and the liquid jetting port 42, and the fourth flow channel 44D connecting the first flow channel 44A and the cylinder chamber 52. Also in the present modification, a gap is made between the outer periphery of the piston 51 and the inner periphery of the cylinder chamber 52. This gap forms the fourth flow channel 44D. As the water-hammer reducing mechanism, the configuration in which the fluid resistance of the fourth flow channel 44D is higher than that of the first flow channel 44A is applied.

When the atomizer 34 is provided with the water-hammer reducing mechanism in this way to reduce damage to the flow channel 44 (the flow channel 44 in the atomizer 34, pipes outside the atomizer 34) caused by a water hammer phenomenon.

Embodiments of the present disclosure have been exemplified above. However, the scope of the present disclosure is not limited to the above embodiments and appropriate variations and modifications are possible within the scope of the claims.

In the above descriptions, the water-hammer reducing mechanism is provided in the hand shower gun or the atomizer. However, the water-hammer reducing mechanism may be provided in a washing unit other than the hand shower gun and the atomizer. Liquid is not limited to pure water or ultrapure water and may be other washing liquid.

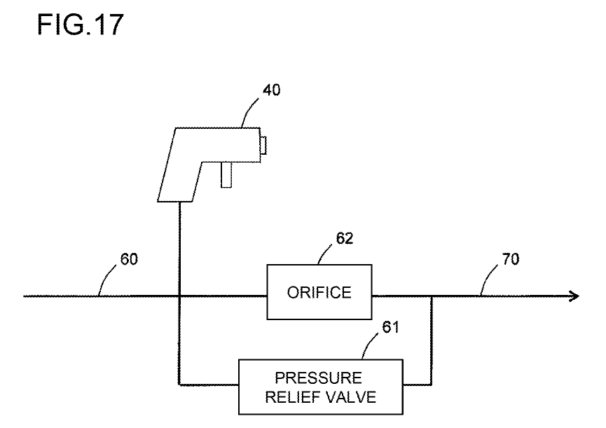

FIG. 17 illustrates a substrate processing apparatus in another embodiment. As illustrated in FIG. 17, the substrate processing apparatus includes a polishing part (not illustrated in FIG. 17) that polishes a substrate in a chamber, the hand shower gun 40 that washes the inside of the chamber, and a liquid supplying line 60 that supplies liquid (pure water) to the hand shower gun 40. A liquid discharging line 70 branches from the liquid supplying line 60. The liquid discharging line 70 is provided with a pressure relief valve 61 as a water-hammer reducing mechanism. The pressure relief valve 61 is placed at a position at the upstream side of the hand shower gun 40 across an orifice 62 on the liquid supplying line 60. When a valve (not illustrated in FIG. 17) in the hand shower gun 40 is closed and the pressure in the liquid supplying line 60 increases, the pressure relief valve 61 operates to reduce damage to a flow channel in the hand shower gun 40 caused by a water hammer phenomenon. Since the pressure relief valve 61 is provided in the liquid supplying line 60 (the liquid discharging line 70 that branches from the liquid supplying line 60) in this way, damage to the flow channel (the flow channel in the hand shower gun 40) caused by a water hammer phenomenon is reduced.

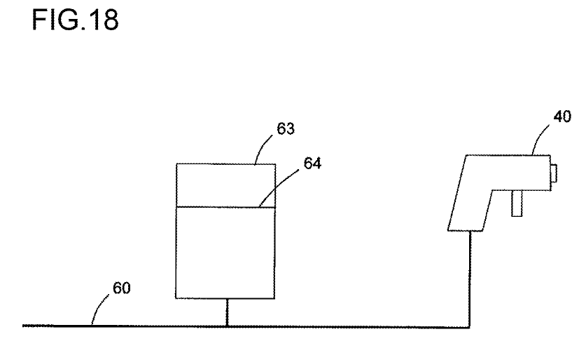

FIG. 18 illustrates a substrate processing apparatus in still another embodiment. As illustrated in FIG. 18, the substrate processing apparatus also includes a polishing part (not illustrated in FIG. 18) that polishes a substrate in a chamber, the hand shower gun 40 that washes the inside of the chamber, and the liquid supplying line 60 that supplies liquid (pure water) to the hand shower gun 40. A water-hammer reducing mechanism in the present embodiment is configured by a buffer tank 63 that is provided in the liquid supplying line 60. The buffer tank 63 includes a diaphragm 64 that operates when a valve (not illustrated in FIG. 18) in the hand shower gun 40 is closed. When the valve (not illustrated in FIG. 18) in the hand shower gun 40 is closed and the pressure in the liquid supplying line 60 increases, the diaphragm 64 operates to reduce damage to the flow channel in the hand shower gun 40 caused by a water hammer phenomenon. Since the buffer tank 63 including the diaphragm 64 is provided in the liquid supplying line 60 in this way, damage to the flow channel (the flow channel in the hand shower gun 40) caused by a water hammer phenomenon is reduced.

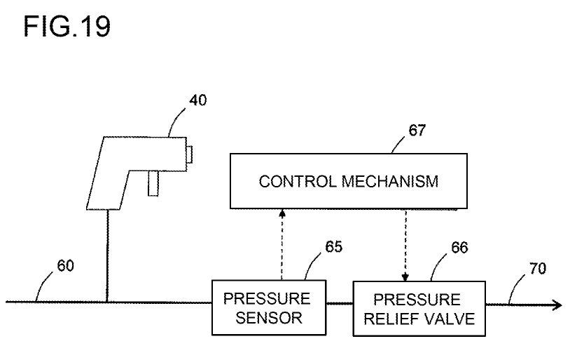

FIG. 19 illustrates a substrate processing apparatus in still another embodiment. As illustrated in FIG. 19, the substrate processing apparatus also includes a polishing part (not illustrated in FIG. 19) that polishes a substrate in a chamber, the hand shower gun 40 that washes the inside of the chamber, and the liquid supplying line 60 that supplies liquid (pure water) to the hand shower gun 40. In the present embodiment, the liquid discharging line 70 branches from the liquid supplying line 60, and the water-hammer reducing mechanism is configured by a pressure sensor 65 and a pressure relief valve 66 that are provided in the liquid discharging line 70. When a valve (not illustrated in FIG. 19) in the hand shower gun 40 is closed, the pressure in the liquid supplying line 60 increases. When the pressure sensor 65 detects the pressure increase, the pressure relief valve 66 operates to lower the pressure in the liquid supplying line 60. More specifically, when detecting the pressure increase in the liquid supplying line 60, the pressure sensor 65 sends a detection signal to a control mechanism 67. When receiving the detection signal from the pressure sensor 65, the control mechanism 67 sends an operation signal to the pressure relief valve 66. When receiving the operation signal from the control mechanism 67, the pressure relief valve 66 lowers the pressure in the liquid supplying line 60. Since the pressure sensor 65 and the pressure relief valve 66 are provided in the liquid supplying line 60 (the liquid discharging line 70 that branches from the liquid supplying line 60) in this way, damage to the flow channel (the flow channel in the hand shower gun 40) caused by a water hammer phenomenon is reduced.

As described above, a substrate processing apparatus according to the present disclosure provides an effect that damage caused by a water hammer phenomenon is reduced. The substrate processing apparatus is useful and may be used as a substrate polishing device or the like, for example.

### REFERENCE SIGNS LIST

1 Housing
3 Polishing part
4 Washing part
5 Control part
34 Atomizer
40 Hand shower gun
41 Liquid supplying port
42 Liquid jetting port
43 Main body
44 Flow channel
44A First flow channel
44B Second flow channel
44C Third flow channel
44D Fourth flow channel
44E Fifth flow channel
45 Valve
46 Operation handle
47 Liquid supplying tube
48 Pressure relief valve
51 Piston
52 Cylinder chamber
52A First area
52B Second area
54 Throttle mechanism (Fluid-resistance adjusting part)
55 Adjusting screw
56 Check valve
60 Liquid supplying line
61 Pressure relief valve
62 Orifice
63 Buffer tank
64 Diaphragm
65 Pressure sensor
66 Pressure relief valve
70 Liquid discharging line

What is claimed is:

1. A substrate processing apparatus comprising:
a chamber for processing a substrate;
a washing unit that performs washing an inside of the chamber; and
a liquid supplying line that supplies liquid to the washing unit, wherein
the washing unit includes:
a main body that has a liquid supplying port and a liquid jetting port;
a flow channel that is formed between the liquid supplying port and the liquid jetting port in the main body; and
a valve that is provided in the flow channel,
in the washing unit, when the valve is opened, the flow channel is opened, thereby causing the liquid jetting port to jet liquid, and when the valve is closed, the flow channel is closed, thereby causing the liquid jetting port to stop jetting liquid, and
the liquid supplying line is provided with a water-hammer reducing mechanism that operates to reduce damage to the flow channel caused by a water hammer phenomenon when the valve is closed.

2. The substrate processing apparatus according to claim 1, wherein
the washing unit includes:
a piston that is provided in the valve and slidingly moves in cooperation with an opening/closing operation of the valve; and
a cylinder chamber that houses the piston,
the flow channel includes a first flow channel between the liquid supplying port and the valve, a second flow channel between the valve and the liquid jetting port, and a fourth flow channel connecting the first flow channel and the cylinder chamber, and
a fluid resistance of the fourth flow channel is higher than a fluid resistance of the first flow channel.

3. The substrate processing apparatus according to claim 2, wherein
the fourth flow channel is provided with a fluid-resistance adjusting part that adjusts the fluid resistance of the fourth flow channel.

4. The substrate processing apparatus according to claim 2, wherein
the cylinder chamber includes a first area that is an area in which the piston slidingly moves when the valve is opened and a second area that is an area at an opposite side of the first area across the piston,
the cylinder chamber is provided with a fifth flow channel connecting the first area and the second area,
the fifth flow channel is provided with a check valve, and
when the valve is opened, the check valve is opened by increase in liquid pressure in the first area, thereby establishing communication between the first area and the second area.
